(19) United States
(12) Patent Application Publication
(10) Pub. No.: US 2026/0082703 A1
(43) Pub. Date: Mar. 19, 2026

(54) CHARGE PUMP CIRCUIT CONFIGURATION IN NONVOLATILE MEMORY

(71) Applicant: Sandisk Technologies, Inc., Milpitas, CA (US)

(72) Inventors: Ankit Rehani, Delhi (IN); V.S.N.K. Chaitanya G, Bengaluru (IN); Indra Kumar K V, Bengaluru (IN); Mohan Vamsi Dunga, Santa Clara, CA (US); Naoki Ookuma, Kita-ku (JP); Bandimata Nagaraj, Anantapur (IN)

(73) Assignee: Sandisk Technologies, Inc., Milpitas, CA (US)

(21) Appl. No.: 18/887,054

(22) Filed: Sep. 17, 2024

(51) Int. Cl. H01L 27/02; G11C 16/08; G11C 16/12; G11C 16/16; G11C 16/26; G11C 16/30; H01L 23/00; H10B 41/27; H10B 41/35; H10B 41/41; H10B 43/27; H10B 43/35; H10B 43/40

(52) U.S. Cl. CPC H10D 89/10; G11C 16/08; G11C 16/12; G11C 16/16; G11C 16/26; G11C 16/30; H10B 41/27; H10B 41/35; H10B 41/41; H10B 43/27; H10B 43/35; H10B 43/40; H10W 90/792

(57) ABSTRACT

Control circuits are configured to receive an input voltage through bond pads located on a surface of a die and generate supply voltages from the input voltage in a plurality of charge pumps located in a charge pump area of the die. The control circuits are further configured to provide the supply voltages to a plurality of voltage regulation circuits, each voltage regulation circuit located in a respective area of the die that corresponds to a portion of the nonvolatile memory array and generate a plurality of corresponding regulated voltages at each of the plurality of voltage regulation circuits for the corresponding portion of the nonvolatile memory array.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power (e.g., a battery).

One type of non-volatile memory has strings of non-volatile memory cells that have a select transistor at each end of the string. Typically, such strings are referred to as NAND strings. A NAND string may have a drain side select transistor at one end that connects the string to a bit line. A NAND string may have a source side select transistor at one end that connects the string to a source line.

Operating a nonvolatile memory may include applying various voltages to memory cells in order to program, read and erase memory cells. In some cases, suitable voltages may be generated voltage using one or more charge pumps. A charge pump may be required to meet certain metrics (e.g., output voltage and current) to ensure that a nonvolatile memory operates satisfactorily. Charge pumps may occupy significant space on a die (e.g., due to relatively large capacitors used in charge pumps).

### BRIEF DESCRIPTION OF THE DRAWINGS

Like-numbered elements refer to common components in the different figures.

FIG. 1 is a functional block diagram of a memory device.

FIGS. 2A-B are block diagrams depicting embodiments of a memory system.

FIG. 3 is a perspective view of a portion of one embodiment of a monolithic three dimensional memory structure.

FIG. 4 illustrates aspects of programming operations according to an example.

FIG. 5 illustrates aspects of erasing operations according to an example.

FIG. 6A depicts an example implementation of a charge pump configured as a single-stage charge pump.

FIG. 6B depicts an example implementation of a charge pump configured as a voltage multiplier.

FIG. 6C depicts an example implementation of a charge pump configured as a single-stage, multi-capacitor charge pump.

FIG. 6D depicts an example implementation of a charge pump configured as a multi-stage charge pump

FIG. 7 illustrates an example of a charge pump including switching regulation circuits.

FIG. 8 illustrates an example of control circuits including voltage regulation circuits connected to charge pumps.

FIG. 9 illustrates an example voltage regulation circuit.

FIG. 10 illustrates an example of a multi-plane memory array.

FIG. 11 illustrates an example arrangement of charge pumps and voltage regulation circuits.

FIG. 12 illustrates another example arrangement of charge pumps and voltage regulation circuits.

FIG. 13 illustrates an example of a separated arrangement of charge pumps and voltage regulation circuits.

FIG. 14 illustrates an example arrangement of routing between charge pumps and separated voltage regulation circuits.

FIG. 15 illustrates an example of a method that includes generating supply voltages in charge pumps in a charge pump area

### DETAILED DESCRIPTION

Techniques are provided for configuring certain control circuits in a memory system. For example, placement of charge pumps and associated voltage regulation circuits may have an impact on system design. According to aspects of the present technology, charge pumps and associated voltage regulation circuits are physically separated with charge pumps located close to external bond pads of a die and corresponding voltage regulation circuits located in areas of the die that correspond to portions of a connected nonvolatile memory array. For example, where the nonvolatile memory array is a multi-plane memory array, a control die may include areas corresponding to each plane and voltage regulation circuits may be located in respective areas.

Locating voltage regulation circuits at dispersed locations that are close to the memory array portions to which they are connected may reduce cross-talk and improve system performance. Locating charge pumps close to bond pads may allow charge pumps to receive relatively high input voltages (e.g., little resistive voltage drop because of short distances). Higher input voltage to a charge pump corresponds to smaller capacitance, which may save space and thereby reduce cost.

Aspects of the present technology are directed to technical problems associated with design of control circuits connected to a memory array (e.g., placement of charge pumps and associated voltage regulation circuits). Aspects of the present technology provide solutions that include locating charge pumps in a charge pump area that is close to bond pads of a die and locating associated voltage regulation circuits at dispersed locations across the die that correspond to locations of corresponding memory array portions (e.g., planes).

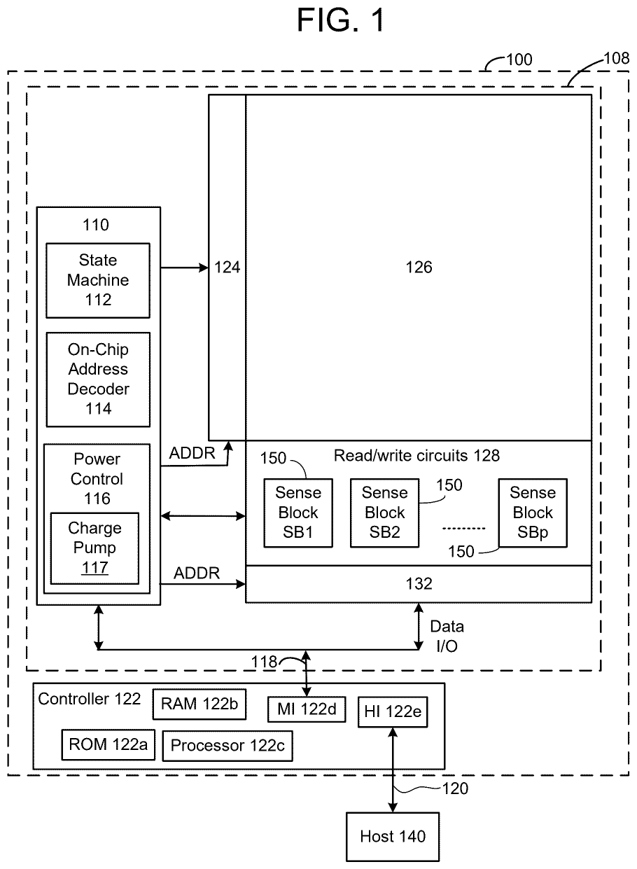

FIG. 1-FIG. 3 describe examples of memory systems that can be used to implement the technology proposed herein. FIG. 1 is a functional block diagram of an example memory system 100. The components depicted in FIG. 1 are electrical circuits. Memory system 100 includes one or more memory dies 108. The one or more memory dies 108 can be complete memory dies or partial memory dies. In one embodiment, each memory die 108 includes a memory structure 126, control circuit 110, and read/write circuits 128. Memory structure 126 is addressable by word lines via a row decoder 124 and by bit lines via a column decoder 132. The read/write/erase circuits 128 include multiple sense blocks 150 including SB1, SB2, . . . , SBp (sensing circuits) and allow a page of memory cells to be read or programmed in parallel. Also, many strings of memory cells can be erased in parallel.

In some systems, a controller 122 is included in the same package (e.g., a removable storage card) as the one or more memory die 108. However, in other systems, the controller can be separated from the memory die 108. In some embodiments the controller will be on a different die than the memory die 108. In some embodiments, one controller 122 will communicate with multiple memory die 108. In other embodiments, each memory die 108 has its own controller. Commands and data are transferred between a host 140 and controller 122 via a data bus 120, and between controller 122 and the one or more memory die 108 via lines 118. In one embodiment, memory die 108 includes a set of input and/or output (I/O) pins that connect to lines 118.

Control circuit 110 cooperates with the read/write circuits 128 to perform memory operations (e.g., write, read, erase and others) on memory structure 126, and includes state machine 112, an on-chip address decoder 114, and a power control circuit 116. In one embodiment, control circuit 110 includes buffers such as registers, ROM fuses and other storage devices for storing default values such as base voltages and other parameters.

The on-chip address decoder 114 provides an address interface between addresses used by host 140 or controller 122 to the hardware address used by the decoders 124 and 132. Power control circuit 116 controls the power and voltages supplied to the word lines, bit lines, and select lines during memory operations. The power control circuit 116 includes voltage circuitry, in one embodiment. Power control circuit 116 includes charge pumps 117 for creating voltages. The sense blocks include bit line drivers. The power control circuit 116 executes under control of the state machine 112, in one embodiment.

State machine 112 and/or controller 122 (or equivalently functioned circuits), in combination with all or a subset of the other circuits depicted in FIG. 1, can be considered a control circuit that performs various functions described herein. The control circuit can include hardware only or a combination of hardware and software (including firmware). For example, a controller programmed by firmware to perform the functions described herein is one example of a control circuit. A control circuit can include a processor, PGA (Programmable Gate Array, FPGA (Field Programmable Gate Array), ASIC (Application Specific Integrated Circuit), integrated circuit or other type of circuit.

The (on-chip or off-chip) controller 122 (which in one embodiment is an electrical circuit) may comprise one or more processors 122c, ROM 122a, RAM 122b, a memory interface (MI) 122d and a host interface (HI) 122e, all of which are interconnected. The storage devices (ROM 122a, RAM 122b) store code (software) such as a set of instructions (including firmware), and one or more processors 122c is/are operable to execute the set of instructions to provide the functionality described herein. Alternatively, or additionally, one or more processors 122c can access code from a storage device in the memory structure, such as a reserved area of memory cells connected to one or more word lines. RAM 122b can be to store data for controller 122, including caching program data (discussed below). Memory interface 122d, in communication with ROM 122a, RAM 122b and processor 122c, is an electrical circuit that provides an electrical interface between controller 122 and one or more memory die 108. For example, memory interface 122d can change the format or timing of signals, provide a buffer, isolate from surges, latch I/O, etc. One or more processors 122c can issue commands to control circuit 110 (or another component of memory die 108) via Memory Interface 122d. Host interface 122e provides an electrical interface with host 140 data bus 120 in order to receive commands, addresses and/or data from host 140 to provide data and/or status to host 140.

In one embodiment, memory structure 126 comprises a three-dimensional memory array of non-volatile memory cells in which multiple memory levels are formed above a single substrate, such as a wafer. The memory structure may comprise any type of non-volatile memory that are monolithically formed in one or more physical levels of arrays of memory cells having an active area disposed above a silicon (or other type of) substrate. In one example, the non-volatile memory cells comprise vertical NAND strings with charge-trapping material.

In another embodiment, memory structure 126 comprises a two-dimensional memory array of non-volatile memory cells. In one example, the non-volatile memory cells are NAND flash memory cells utilizing floating gates. Other types of memory cells (e.g., NOR-type flash memory) can also be used. The exact type of memory array architecture or memory cell included in memory structure 126 is not limited to the examples above.

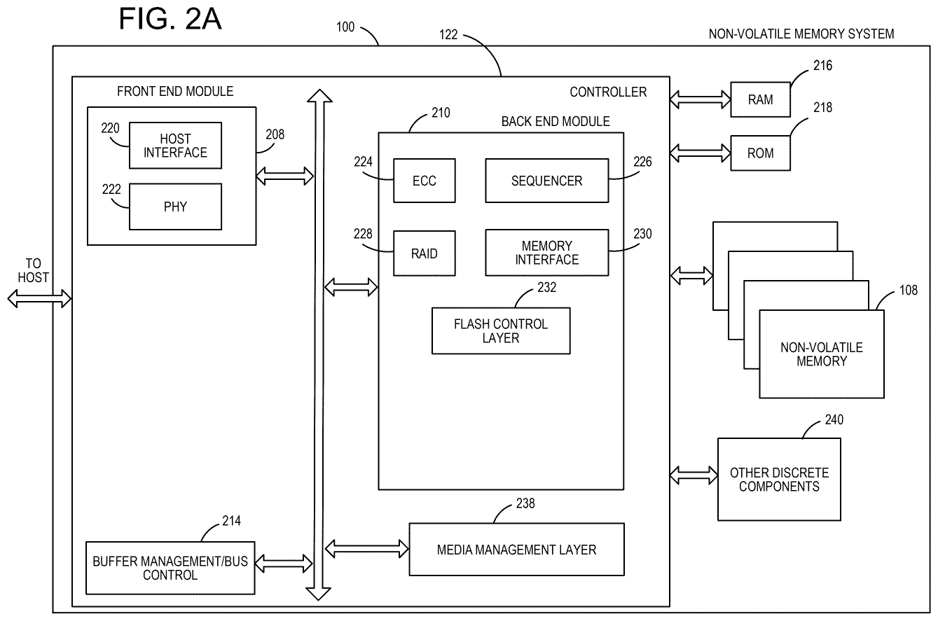

FIG. 2A is a block diagram of example memory system 100, depicting more details of one embodiment of controller 122. The controller in FIG. 2A is a flash memory controller but note that the non-volatile memory die 108 is not limited to flash. Thus, the controller 122 is not limited to the example of a flash memory controller. As used herein, a flash memory controller is a device that manages data stored on flash memory and communicates with a host, such as a computer or electronic device. A flash memory controller can have various functionality in addition to the specific functionality described herein. For example, the flash memory controller can format the flash memory to ensure the memory is operating properly, map out bad flash memory cells, and allocate spare memory cells to be substituted for future failed cells. Some part of the spare cells can be used to hold firmware to operate the flash memory controller and implement other features. In operation, when a host needs to read data from or write data to the flash memory, it will communicate with the flash memory controller. If the host provides a logical address to which data is to be read/written, the flash memory controller can convert the logical address received from the host to a physical address in the flash memory. (Alternatively, the host can provide the physical address). The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between controller 122 and non-volatile memory die 108 may be any suitable flash interface, such as Toggle Mode 200, 400, or 800. In one embodiment, memory system 100 may be a card-based system, such as a secure digital (SD) or a micro secure digital (micro-SD) card. In an alternate embodiment, memory system 100 may be part of an embedded memory system. For example, the flash memory may be embedded within the host. In other example, memory system 100 can be in the form of a solid state drive (SSD).

In some embodiments, memory system 100 includes a single channel between controller 122 and non-volatile memory die 108, the subject matter described herein is not limited to having a single memory channel. For example, in some memory system architectures, 2, 4, 8 or more channels may exist between the controller and the memory die, depending on controller capabilities. In any of the embodiments described herein, more than a single channel may exist between the controller and the memory die, even if a single channel is shown in the drawings.

As depicted in FIG. 2A, controller 122 includes a front end module 208 that interfaces with a host, a back end module 210 that interfaces with the one or more non-volatile memory die 108, and various other modules that perform functions which will now be described in detail.

The components of controller 122 depicted in FIG. 2A may take the form of a packaged functional hardware unit (e.g., an electrical circuit) designed for use with other components, a portion of a program code (e.g., software or firmware) executable by a (micro) processor or processing circuits that usually performs a particular function of related functions, or a self-contained hardware or software component that interfaces with a larger system, for example. For example, each module may include an application specific integrated circuit (ASIC), a Field Programmable Gate Array (FPGA), a circuit, a digital logic circuit, an analog circuit, a combination of discrete circuits, gates, or any other type of hardware or combination thereof. Alternatively, or in addition, each module may include software stored in a processor readable device (e.g., memory) to program a processor for controller 122 to perform the functions described herein. The architecture depicted in FIG. 2A is one example implementation that may (or may not) use the components of controller 122 depicted in FIG. 1 (i.e., RAM, ROM, processor, interface).

Referring again to modules of the controller 122, a buffer manager/bus control 214 manages buffers in random access memory (RAM) 216 and controls the internal bus arbitration of controller 122. A read only memory (ROM) 218 stores system boot code. Although illustrated in FIG. 2A as located separately from the controller 122, in other embodiments one or both of the RAM 216 and ROM 218 may be located within the controller. In yet other embodiments, portions of RAM and ROM may be located both within the controller 122 and outside the controller. Further, in some implementations, the controller 122, RAM 216, and ROM 218 may be located on separate semiconductor die.

Front end module 208 includes a host interface 220 and a physical layer interface (PHY) 222 that provide the electrical interface with the host or next level storage controller. The choice of the type of host interface 220 can depend on the type of memory being used. Examples of host interfaces 220 include, but are not limited to, SATA, SATA Express, SAS, Fibre Channel, USB, PCIe, and NVMe. The host interface 220 typically facilitates transfer for data, control signals, and timing signals.

Back end module 210 includes an error correction code (ECC) engine 224 that encodes the data bytes received from the host and decodes and error corrects the data bytes read from the non-volatile memory. A command sequencer 226 generates command sequences, such as program and erase command sequences, to be transmitted to non-volatile memory die 108. A RAID (Redundant Array of Independent Dies) module 228 manages generation of RAID parity and recovery of failed data. The RAID parity may be used as an additional level of integrity protection for the data being written into the memory system 100. In some cases, the RAID module 228 may be a part of the ECC engine 224. Note that the RAID parity may be added as an extra die or dies as implied by the common name, but it may also be added within the existing die, e.g., as an extra plane, or extra block, or extra WLs within a block. A memory interface 230 provides the command sequences to non-volatile memory die 108 and receives status information from non-volatile memory die 108. In one embodiment, memory interface 230 may be a double data rate (DDR) interface, such as a Toggle Mode 200, 400, or 800 interface. A flash control layer 232 controls the overall operation of back end module 210.

Additional components of memory system 100 illustrated in FIG. 2A include media management layer 238, which performs wear leveling of memory cells of non-volatile memory die 108. Memory system 100 also includes other discrete components 240, such as external electrical interfaces, external RAM, resistors, capacitors, or other components that may interface with controller 122. In alternative embodiments, one or more of the physical layer interface 222, RAID module 228, media management layer 238 and buffer management/bus controller 214 are optional components that are not necessary in the controller 122.

The Flash Translation Layer (FTL) or Media Management Layer (MML) 238 may be integrated as part of the flash management that may handle flash errors and interfacing with the host. In particular, MML may be a module in flash management and may be responsible for the internals of NAND management. In particular, the MML 238 may include an algorithm in the memory device firmware which translates writes from the host into writes to the memory structure 126 of memory die 108. The MML 238 may be needed because: 1) the memory may have limited endurance; 2) the memory structure 126 may only be written in multiples of pages; and/or 3) the memory structure 126 may not be written unless it is erased as a block (or a tier within a block in some embodiments). The MML 238 understands these potential limitations of the memory structure 126 which may not be visible to the host. Accordingly, the MML 238 attempts to translate the writes from host into writes into the memory structure 126.

Controller 122 may interface with one or more memory dies 108. In one embodiment, controller 122 and multiple memory dies (together comprising memory system 100) implement a solid state drive (SSD), which can emulate, replace or be used instead of a hard disk drive inside a host, as a NAS device, in a laptop, in a tablet, in a server, etc. Additionally, the SSD need not be made to work as a hard drive.

Some embodiments of a non-volatile storage system will include one memory die 108 connected to one controller 122. However, other embodiments may include multiple memory die 108 in communication with one or more controllers 122. In one example, the multiple memory die can be grouped into a set of memory packages. Each memory package includes one or more memory die in communication with controller 122. In one embodiment, a memory package includes a printed circuit board (or similar structure) with one or more memory die mounted thereon. In some embodiments, a memory package can include molding material to encase the memory dies of the memory package. In some embodiments, controller 122 is physically separate from any of the memory packages.

In one embodiment, the control circuit(s) (e.g., control circuits 110) are formed on a first die, referred to as a control die, and the memory array (e.g., memory structure 126) is formed on a second die, referred to as a memory die. For example, some or all control circuits (e.g., control circuit 110, row decoder 124, column decoder 132, and read/write circuits 128) associated with a memory may be formed on the same control die. A control die may be bonded to one or more corresponding memory die to form an integrated memory assembly. The control die and the memory die may have bond pads arranged for electrical connection to each other. Bond pads of the control die and the memory die may be aligned and bonded together by any of a variety of bonding techniques, depending in part on bond pad size and bond pad spacing (i.e., bond pad pitch). In some embodiments, the bond pads are bonded directly to each other, without solder or other added material, in a so-called Cu-to-Cu bonding process. In some examples, dies are bonded in a one-to-one arrangement (e.g., one control die to one memory die). In some examples, there may be more than one control die and/or more than one memory die in an integrated memory assembly. In some embodiments, an integrated memory assembly includes a stack of multiple control die and/or multiple memory die. In some embodiments, the control die is connected to, or otherwise in communication with, a memory controller. For example, a memory controller may receive data to be programmed into a memory array. The memory controller will forward that data to the control die so that the control die can program that data into the memory array on the memory die.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 307. One or more integrated memory assemblies 307 may be used in a memory package in memory system 100. The integrated memory assembly 307 includes two types of semiconductor die (or more succinctly, “die”). Memory die 301 includes memory structure 126

Control die 311 includes column control circuits 364, row control circuits 320 and system control logic 360 (including state machine 312, power control module 316 (including charge pumps 117), storage 366, and memory interface 368). In some embodiments, control die 311 is configured to connect to the memory array 126 in the memory die 301. FIG. 2B shows an example of the peripheral circuits, including control circuits, formed in a peripheral circuit or control die 311 coupled to memory array 126 formed in memory die 301. System control logic 360, row control circuits 320, and column control circuits 364 are located in control die 311. In some embodiments, all or a portion of the column control circuits 364 and all or a portion of the row control circuits 320 are located on the memory die 301. In some embodiments, some of the circuits in the system control logic 360 are located on the on the memory die 301.

System control logic 360, row control circuits 320, and column control circuits 364 may be formed by a common process (e.g., CMOS process), so that adding elements and functionalities, such as ECC, more typically found on a memory controller 102 may require few or no additional process steps (i.e., the same process steps used to fabricate memory controller 102 may also be used to fabricate system control logic 360, row control circuits 320, and column control circuits 364). Thus, while moving such circuits from a die such as memory die 301 may reduce the number of steps needed to fabricate such a die, adding such circuits to a die such as control die 311 may not require many additional process steps.

FIG. 2B shows column control circuits 364 including sense block(s) 350 on the control die 311 coupled to memory array 126 on the memory die 301 through electrical paths 370. For example, electrical paths 370 may provide electrical connection between column decoder 332, driver circuits 372, and block select 373 and bit lines of memory array (or memory structure) 126. Electrical paths may extend from column control circuits 364 in control die 311 through pads on control die 311 that are bonded to corresponding pads of the memory die 301, which are connected to bit lines of memory structure 126. Each bit line of memory structure 126 may have a corresponding electrical path in electrical paths 370, including a pair of bond pads, which connects to column control circuits 364. Similarly, row control circuits 320, including row decoder 324, array drivers 374, and block select 376 are coupled to memory array 126 through electrical paths 308. Each of electrical path 308 may correspond to a word line, dummy word line, or select gate line. Additional electrical paths may also be provided between control die 311 and memory die 301. FIGS. 2A and 2B are simplified schematic illustrations. Locations of circuits shown are not intended to accurately represent physical locations of corresponding physical circuits in a die. For example, locations of system control logic 360, row control circuits 320 and column control circuits 364 of FIG. 2B are not intended to represent physical locations of these circuits in control die 311.

In some embodiments, there is more than one control die 311 and/or more than one memory die 301 in an integrated memory assembly 307. In some embodiments, the integrated memory assembly 307 includes a stack of multiple control die 311 and multiple memory dies 301. In some embodiments, each control die 311 is affixed (e.g., bonded) to at least one of the memory dies 301.

The exact type of memory array architecture or memory cell included in memory structure 126 is not limited to the examples above. Many different types of memory array architectures or memory cell technologies can be used to form memory structure 126. No particular non-volatile memory technology is required for purposes of the new claimed embodiments proposed herein. Other examples of suitable technologies for memory cells of the memory structure 126 include ReRAM memories, magnetoresistive memory (e.g., MRAM, Spin Transfer Torque MRAM, Spin Orbit Torque MRAM), phase change memory (e.g., PCM), and the like. Examples of suitable technologies for architectures of memory structure 126 include two dimensional arrays, three dimensional arrays, cross-point arrays, stacked two dimensional arrays, vertical bit line arrays, and the like.

One example of a ReRAM, or PCMRAM, cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse but includes a (continuous or non-continuous) vibration or burst of sound, current, voltage light, or other wave.

A person of ordinary skill in the art will recognize that the technology described herein is not limited to a single specific memory structure, but covers many relevant memory structures within the spirit and scope of the technology as described herein and as understood by one of ordinary skill in the art.

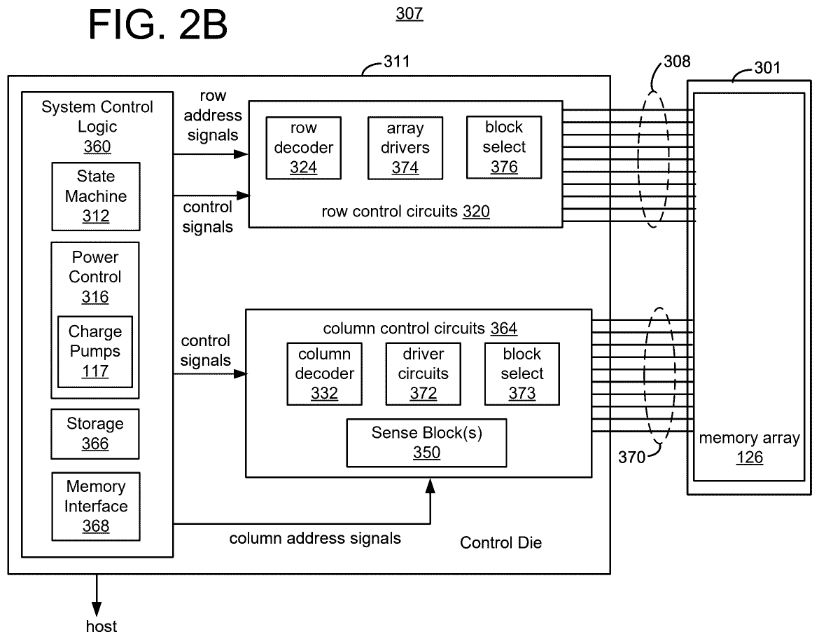

FIG. 3 is a perspective view of a portion of one example embodiment of a monolithic three dimensional memory array that can comprise memory structure 126, which includes a plurality non-volatile memory cells. For example, FIG. 3 shows a portion of one block of memory. The structure depicted includes a set of bit lines BL positioned above a stack of alternating layers of dielectric material and conductive material on a substrate. For example, one of the dielectric layers is marked as D and one of the conductive layers (also called word line layers) is marked as W. The number of alternating dielectric layers and conductive layers can vary based on specific implementation requirements. One set of embodiments includes between 108-300 alternating dielectric layers and conductive layers. One example embodiment includes 96 data word line layers, 8 select layers, 6 dummy word line layers and 110 dielectric layers. More or less than 108-300 layers can also be used. Data word line layers have data memory cells. Dummy word line layers have dummy memory cells. As will be explained below, the alternating dielectric layers and conductive layers are divided into “fingers” in regions that are separated by local interconnects LI. FIG. 3 shows two regions, each with respective NAND strings, and two local interconnects LI. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data.

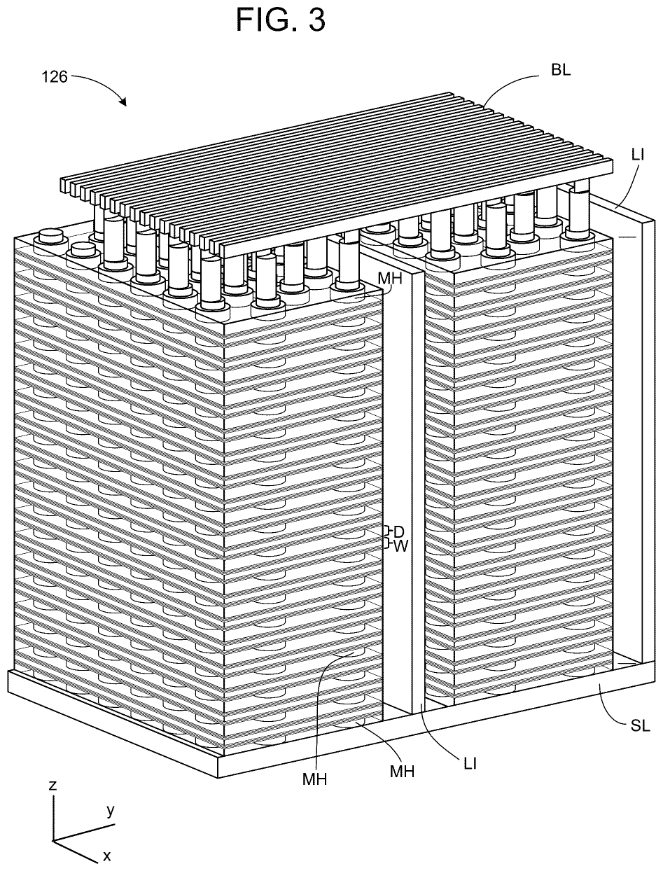

FIG. 4 shows threshold voltage distributions for eight data states, S0 to S7, corresponding to three bits of data per cell (Three Level Cell, or TLC). Also shown are seven read reference voltages, Vr1, Vr2, Vr3, Vr4, Vr5, Vr6, and Vr7 for reading data from memory cells. By testing (e.g., performing sense operations) whether the threshold voltage of a given memory cell is above or below the seven read reference voltages, the system can determine what data state (i.e., S0, S1, S2, S3, . . . ) a memory cell is in.

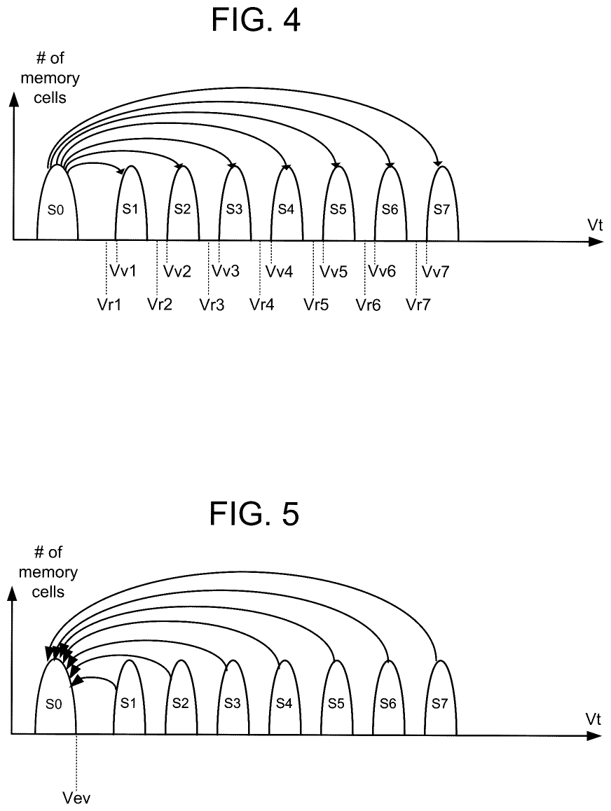

FIG. 4 also shows seven verify reference voltages, Vv1, Vv2, Vv3, Vv4, Vv5, Vv6, and Vv7 used in read verify steps during a programming operation. When programming memory cells to data state S1, the system will test whether those memory cells have a threshold voltage greater than or equal to Vv1. When programming memory cells to data state S2, the system will test whether the memory cells have threshold voltages greater than or equal to Vv2. When programming memory cells to data state S3, the system will determine whether memory cells have their threshold voltage greater than or equal to Vv3. When programming memory cells to data state S4, the system will test whether those memory cells have a threshold voltage greater than or equal to Vv4. When programming memory cells to data state S5, the system will test whether those memory cells have a threshold voltage greater than or equal to Vv5. When programming memory cells to data state S6, the system will test whether those memory cells have a threshold voltage greater than or equal to Vv6. When programming memory cells to data state S7, the system will test whether those memory cells have a threshold voltage greater than or equal to Vv7. FIG. 5A also shows Vev, which is a voltage level to test whether a memory cell has been properly erased (e.g., whether a memory cell is in the S0 data state).

In general, during sensing of verify and read operations, the selected word line is connected to a voltage (one example of a reference signal or read voltage), a level of which is specified for each read operation (e.g., see read compare levels Vr1, Vr2, Vr3, Vr4, Vr5, Vr6, and Vr7, of FIG. 5) or verify operation (e.g. see verify target levels Vv1, Vv2, Vv3, Vv4, Vv5, Vv6, and Vv7 of FIG. 5A) in order to sense whether a threshold voltage of the concerned memory cell has reached such level. After applying the read voltage to the word line, the conduction current of the memory cell is measured to determine whether the memory cell turned on (conducted current) in response to the voltage applied to the word line. If the conduction current is measured to be greater than a certain value (e.g., Isense), then it is assumed that the memory cell turned on and the voltage applied to the word line is greater than the threshold voltage of the memory cell. If the conduction current is not measured to be greater than the certain value, then it is assumed that the memory cell did not turn on and the voltage applied to the word line is not greater than the threshold voltage of the memory cell. During a read or verify process, the unselected data memory cells are provided with one or more read pass voltages (also referred to as bypass voltages) at their control gates so that these data memory cells will operate as pass gates (e.g., conducting current regardless of whether they are programmed or erased), select gates of selected NAND strings are provided with sufficient voltage (e.g., select voltages via select lines) to make corresponding select transistors conductive (“turn on”) and dummy memory cells of selected NAND strings are provided with sufficient voltage (e.g., dummy word line voltage via dummy word lines) to make corresponding dummy memory cells conductive.

FIG. 5 shows an example of an erase operation in which charge is removed from memory cells of threshold voltage distributions for seven data states, S1 to S7, which results in all programmed memory cells being in erased state S0. Also shown is erase verify voltage, Vev for verifying memory cells are in state S0. In an example, a high voltage (erase voltage) is applied to word lines of a block to erase memory cells. For example, 20 volts may be used as an erase voltage while lower voltages may be used to program and read memory cells. Programming memory cells may use voltage pulses of different voltages and reading may apply different read voltages and read pass voltages to word lines. Additional voltages may be applied to dummy word lines, select lines and other components. Thus, a range of voltages may be used in various access operations (read, write and erase) directed to memory cells. In general, such voltages are not all directly supplied to a memory die (e.g., memory die 108) or integrated memory assembly and may be generated on-chip. For example, memory die 108 may receive a supply voltage (e.g., 1.8 volts or 3.0 volts) and may generate different voltages (e.g., erase voltage, read voltages, program voltages) from the supply voltage using appropriate power circuits. An example of a circuit that may be used to generate a relatively high voltage (e.g., erase voltage) from a lower supply voltage is a charge pump.

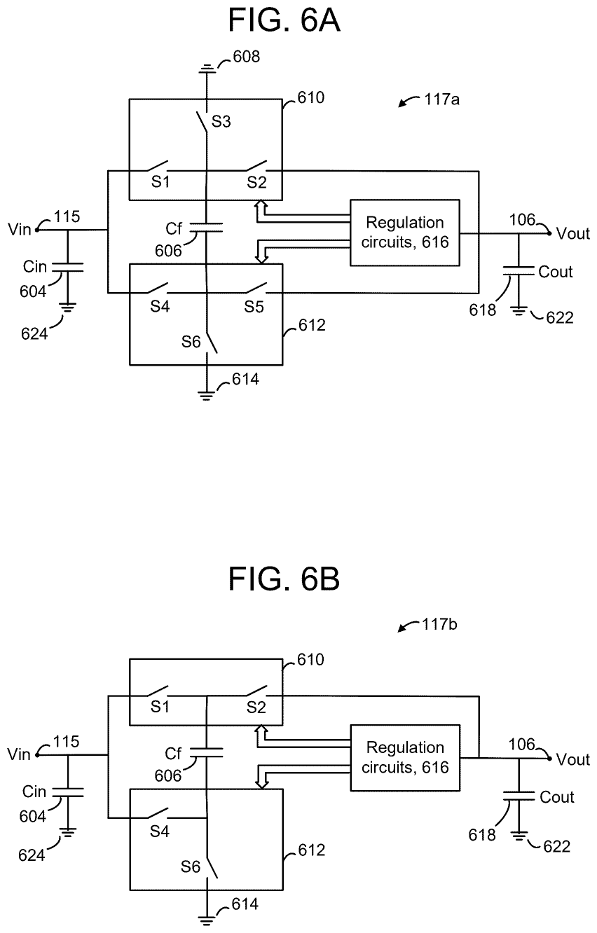

FIGS. 6A to 6D provide example configurations of a charge pump (e.g., charge pump 117 in FIGS. 1 and 2B). A charge pump can use one or more capacitor to transfer charge from an input node to an output node.

FIG. 6A depicts an example implementation of the charge pump 117 configured as a single-stage charge pump 117a. A charge pump generally refers to a switching voltage converter that employs an intermediate capacitive storage element which is sometimes referred to as a flying capacitor or a charge transfer capacitor. One or more capacitors can be used. Moreover, a charge pump can include multiple stages connected in series to obtain special features such as a high output voltage and a greater range of output voltages. A charge pump can be constructed or configured for providing voltage conversion for applications including: multiplier, divider, inverter and follower. The principles discussed herein can be applied to charge pumps having one or more stages and having one or more capacitors in a stage. The charge pump 117a is a generalized embodiment which can be controlled for multiplier, divider, inverter and follower applications. The charge pump 117a includes an input node 115 at which an input voltage (Vin) is applied. For example, Vin may be equal to a fixed power supply voltage sometimes referred to as Vdd or Vcc in a semiconductor chip. Or, Vin may be a clamped voltage which is lower than the power supply voltage. Charge from the voltage is maintained in an input capacitor Cin 604 which is connected to a ground node 624.

A first set of switches 610 and a second set of switches 612 are controlled by switching regulation circuits 616 (regulation circuits) to transfer charge from the input node 115 to a capacitor Cf 606, and from Cf 606 to an output node 106. Vout is a resulting voltage at the output node 106 and can be greater than or less than Vin. The output node is coupled to an output capacitor Cout 618, which is connected to a ground node 622. The first set of switches 610 includes switches S1, S2 and S3 which are star-connected to one terminal (such as the top conductor) of Cf. The switches may be MOSFETs, bipolar junction transistors, relay switches, or the like. S1 connects the top conductor of Cf 606 to the input node 115 to receive a charge from Vin. S2 connects the top conductor of Cf 606 to the output node 106 to transfer its charge to the output node. S3 connects the top conductor of Cf 606 to a ground node 608. Similarly, the second set of switches 612 includes switches S4, S5 and S6 which are star-connected to another terminal (such as the bottom conductor) of Cf 606. S4 connects the bottom conductor of Cf 606 to the input node 115 to receive a charge from Vin. S5 connects the bottom conductor of Cf 606 to the output node 106 to transfer its charge to the output node. S6 connects the bottom conductor of Cf 606 to a ground node 614.

FIG. 6B depicts an example implementation of the charge pump 117 configured as a voltage multiplier 117b. A voltage multiplier, or step-up charge pump, in general, provides Vout>Vin. In this configuration, the voltage multiplier provides 2×Vin>Vout>Vin, and the switches S3 and S5 of FIG. 6A are not needed. In a charging phase, the regulation circuits 616 provides the switches with appropriate control signals so that S1 is closed, e.g., conductive, and S2 is open, e.g., non-conductive, so that Cf 606 is charged via S1. Further, S4 is open and S6 is closed so that the bottom conductor of Cf 606 is connected to the ground node 614. In a discharging phase, S1 is open and S2 is closed, so that Cf 606 is discharged, at least in part, to the output node 106 via S2. Further, S4 is closed and S6 is open.

FIG. 6C depicts an example implementation of the charge pump 117 configured as a single-stage, multi-capacitor charge pump 117c. In this example, multiple flying capacitors are provided in a single stage. While two capacitors are provided as an example, more than two may be used. There are many possible charge pump configurations with multiple flying capacitors. The charge pump 117c is configured as a voltage multiplier in which Vout≈3×Vin. Capacitors Cf1 642 and Cf2 644 are provided. A set of switches 641 includes switches S1 to S7. S2 and S5 are connected to ground nodes 646 and 648, respectively. During a charging phase, switches S2, S3, S5, and S6 are closed, while S1, S4 and S7 are open, so that both flying capacitors Cf1 and Cf2 are connected in parallel and charged to the input voltage. During a discharging phase, switches S1, S4 and S7 are closed, and S2, S3, S5 and S6 are open, so that the flying capacitors are connected in series between the input node 115 and the output node 106. This effectively creates an output voltage of approximately three times the input voltage.

The use of multiple flying capacitors in a single stage can provide a ratio between Vout and Vin, e.g., Vout=1.5×Vin, 3×Vin, etc., or Vout=½×Vin, ⅓×Vin, etc. For greater flexibility, a multi-stage charge pump, such as described below, can be used.

FIG. 6D depicts an example implementation of the charge pump 117 configured as a multi-stage charge pump 117d. Vin is provided at input node 115 so that Vout is obtained at an output node 106. As an example, three stages 658, 666 and 674 are provided. Two or more stages may be used. Each stage can include switches and one or more flying capacitors as discussed previously, for example. At the input, a capacitor Cin 654 is connected at one of its conductive layers to a ground node 656. At a node 660 which is between the first stage 658 and the second stage 666, a capacitor Ca 662 is connected at one of its conductive layers to a ground node 664. At a node 668 which is between the second stage 666 and the third stage 674, a capacitor Cb 670 is connected at one of its conductive layers to a ground node 672. Finally, at the output node 106, an output capacitor Cout 678 is connected at one of its conductive layers to a ground node 630. A multi-stage charge pump can provide greater flexibility in terms of providing a greater range of output voltages. Further, each stage can include one or more capacitors to provide even greater flexibility.

The multi-stage charge pump 117d is operated under the control of regulation circuits 667 which controls switching in each stage. Note that it is also possible to provide regulation circuits in each stage, additionally or alternatively. Charge is transferred from the input node 115 of the first stage to a flying capacitor (not shown) in the first stage 658, and from the flying capacitor of the first stage to the node 660. Charge is then transferred from the node 660 of the second stage to a flying capacitor (not shown) in the second stage, and from the flying capacitor of the second stage to the node 668. Charge is then transferred from the node 668 to a flying capacitor (not shown) in the third stage, and from the flying capacitor of the third stage to the output node 106, assuming there are no further stages.

Example charge pumps 117a-d of FIGS. 6A-D have a charging phase and a discharging phase. Switches (e.g., switches S1-7) are switched, or toggled, according to phase by control signals from regulation circuits 616, 667. For example, switching regulation circuits 616, 667 may send a series of voltage pulses to cause switches S1-7 to alternate on/off or off/on and thereby provide an output current at output node 106. Regulation circuits 616 are connected to output node 106 to respond to changes in voltage, Vout, at output node 106 (e.g., Vout may be controlled by regulation circuits 616 in a feedback loop). Regulation circuits 667 are connected to output nodes 660, 668 and 106 of each switching stage to respond to changes in respective stage output voltages (e.g., multiple feedback loops). For example, when regulation circuits 667 determine that output voltage, Vout, is below a setpoint, regulation circuits 616 may send pulses to generate an output current, which causes Vout to increase as output capacitor, Cout, charges up. When regulation circuits 667 determine that output voltage, Vout, is above the setpoint, regulation circuits 616 may stop sending pulses, which may cause output capacitor, Cout, to discharge. In a given phase some switches may be open (off) and other switches may be closed (on) according to the signals they receive (e.g., some may receive an inverted signal) and/or switch configuration (e.g., some normally-on and some normally-off)

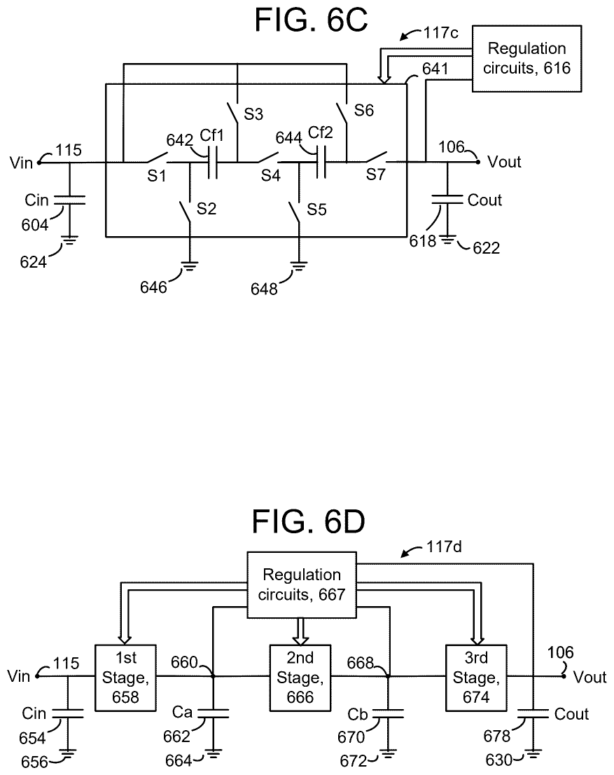

FIG. 7 shows an example implementation of switching regulation circuits 616 of charge pump 117 (e.g., any one of charge pumps 117a, 117b, 117c or 117d). Switching regulation circuits 616 have an output channel 880 that connects to switches of switching stage 882 (e.g., one or more traces leading to individual switches S1, S2, S3 . . . of a switching stage). An output signal of switching regulation circuits 616 may control switching (toggling) of switches of switching stage 882 (e.g. pulses toggling switches) to maintain output voltage, Vout, of charge pump 117.

Switching regulation circuits 616 include a voltage divider 884, which is connected between output node 106 and a ground node 886. Voltage divider 884 includes two resistors, R1 and R2, which are selected to provide a voltage at an intermediate node 888 that is a predetermined fraction of output voltage Vout (e.g., ½, ¼, 1/10, or other fraction). The voltage at node 888 follows Vout and is connected to a first input of a comparator 890. A reference voltage, Vref, is applied to a second input of comparator 890 (e.g., comparator 890 has a first input connected to output node 106 through voltage divider 884 and a second input connected to reference voltage, Vref). Comparator 890 is configured to provide a comparator output signal 892 indicating when output voltage Vout at output node 106 is below a predetermined voltage (e.g., Vref may be set to cause switching of comparator output signal 892 of comparator 890 when Vout is at the predetermined voltage). Comparator output signal 892 is provided to switch 894 (e.g., on a first switch input), which also receives a clock signal 896 (e.g., on a second switch input). Switch 894 provides an output signal 898 on output channel 880 that depends on its inputs. For example, when comparator output signal 892 indicates that Vout is below the predetermined voltage, switch 894 is configured to provide pulses of a (e.g., passing through pulses of clock signal 896) on output channel 880, which causes switching of switching stage 882 and generation of an output current. When comparator output signal 892 indicates that Vout is above the predetermined voltage, switch 894 is configured not to provide pulses on output channel 880 so that no switching occurs and no output current is generated by switching stage 882. As a result, output signal 898 includes fewer pulses than clock signal 896 corresponding to times when Vout was above the predetermined voltage.

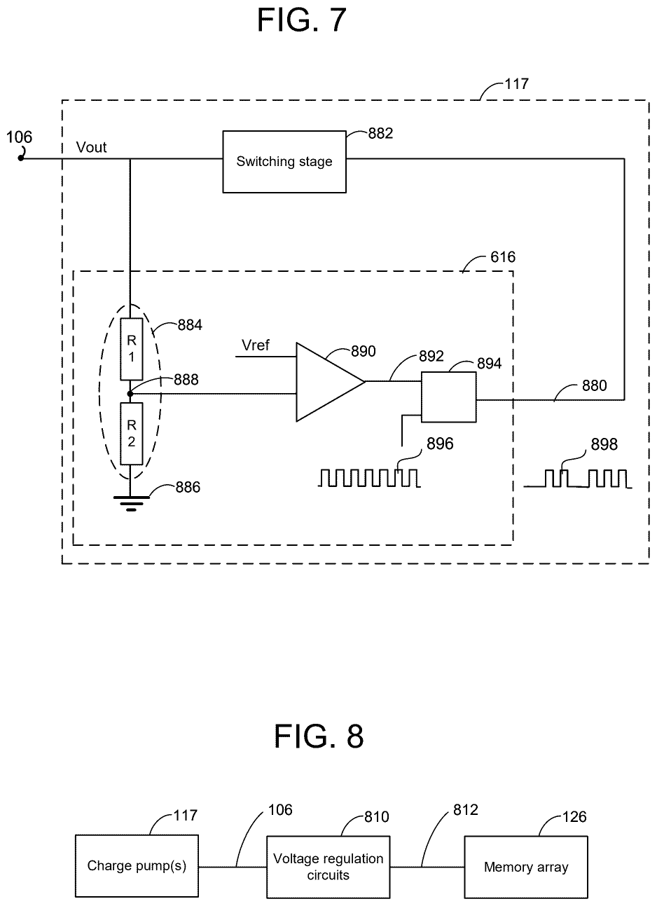

In addition to switching regulation circuits 616, used to control Vout by regulating switching of one or more switching stages, an output voltage provided by a charge pump may be regulated prior to being supplied to a memory array. FIG. 8 illustrates an example of voltage regulation circuits 810 connected to output node 106 of charge pump 117 to receive Vout and connected to node 812 to provide one or more regulated voltages to memory array 126 (e.g., to one or more selected components of memory array 126 such as word lines, bit lines, select lines, etc.). For example, Vout from charge pump 117 may be a relatively noisy output (e.g., having significant voltage variation) which may be reduced by voltage regulation circuits 810 to provide a less noisy (cleaner) voltage for use in a memory array (e.g., to apply to components of a memory array during read, write and erase operations). Voltage may be reduced from a supply voltage of a charge pump (e.g., Vout) to a suitable voltage to be applied (e.g., to a word line).

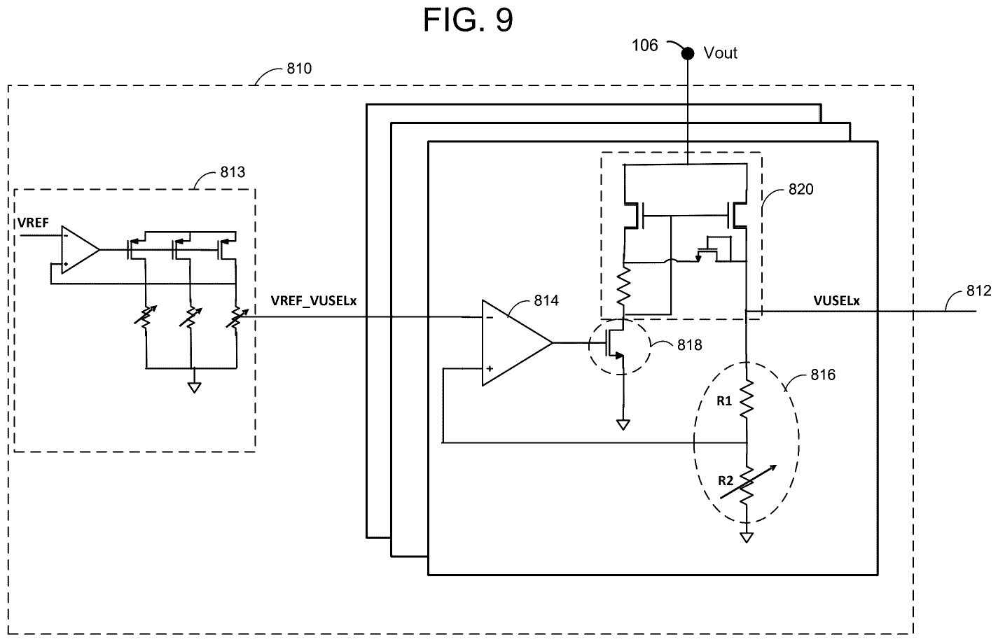

FIG. 9 shows an example of voltage regulation circuits 810 which is connected to receive Vout from output node 106 (e.g., from a charge pump). Voltage regulation circuits 810 include a reference voltage trim circuit 813, which receives a reference voltage VREF and outputs an adjusted (trimmed) reference voltage VREF_VUSELx, which may be set to a desired voltage level (e.g., offset from VREF by a configurable amount). The adjusted reference voltage, VREF-VUSELx, is provided to an op-amp 814, which also receives a feedback signal through an adjustable voltage divider 816 from node 812 (e.g., feedback from output of voltage regulation circuit 810). For example, the feedback signal from voltage divider 816 may be set by adjusting variable resistor R2. The output of op-amp 814 controls a transistor 818, which is connected to one branch of a current mirror 820, while the other branch of current mirror 820 is connected to node 812 and to voltage divider 816. The output of voltage regulation circuit 810 may be less noisy than Vout from a charge pump and may be set to an appropriate voltage that is less than Vout (e.g., by setting VREF_VUSELx and/or R2).

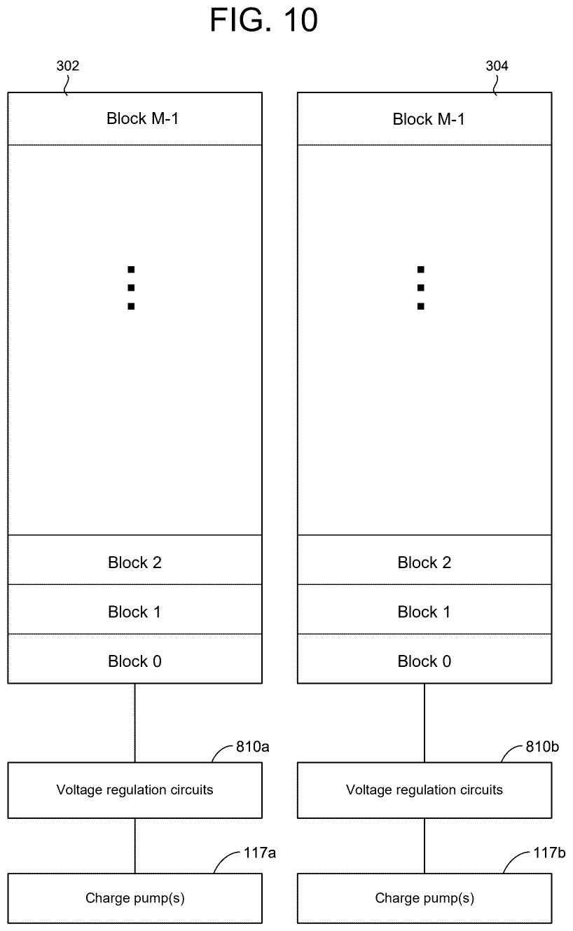

FIG. 10 is a block diagram explaining one example organization of a memory structure (e.g., memory structure 126), which is divided into two planes 302 and 304. Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, memory cells can be grouped into blocks for other reasons, such as to organize the memory structure 126 to enable the signaling and selection circuits. In some embodiments, a block represents a groups of connected memory cells as the memory cells of a block share a common set of word lines. Blocks may be connected by bit lines that are shared by multiple blocks. While two planes are illustrated in this example, in other examples, a memory die may include four, eight, sixteen or more planes that may each have corresponding control circuits (e.g., control circuits to allow operation of planes individually).

In the example of FIG. 10, each plane is connected to corresponding voltage regulation circuits and charge pumps. For example, first plane 302 is connected to first charge pumps 117a through first voltage regulation circuits 810a while second plane 304 is connected to second charge pumps 117b through second voltage regulation circuits 810b (first and second charge pumps 117a-b and voltage regulation circuits 810a-b may be implemented as previously shown or otherwise). This configuration may facilitate separate operation of different planes.

Multiple capacitors may be used in each charge pump (e.g., in first and second charge pumps 117a-b). The capacitors may be relatively large components so that charge pumps may occupy significant area on a die. For example, charge pumps 117 of FIG. 2B (e.g., including first and second charge pumps 117a-b) may occupy a large portion of control die 311 (e.g., more than 10 percent). As memory capacity expands (e.g., as more layers are added in NAND memory, each layer having multiple planes) more charge pumps are needed and the area occupied on a control die may increase accordingly. The configuration (e.g., physical arrangement) of such charge pumps and of corresponding voltage regulation circuits may affect the area occupied.

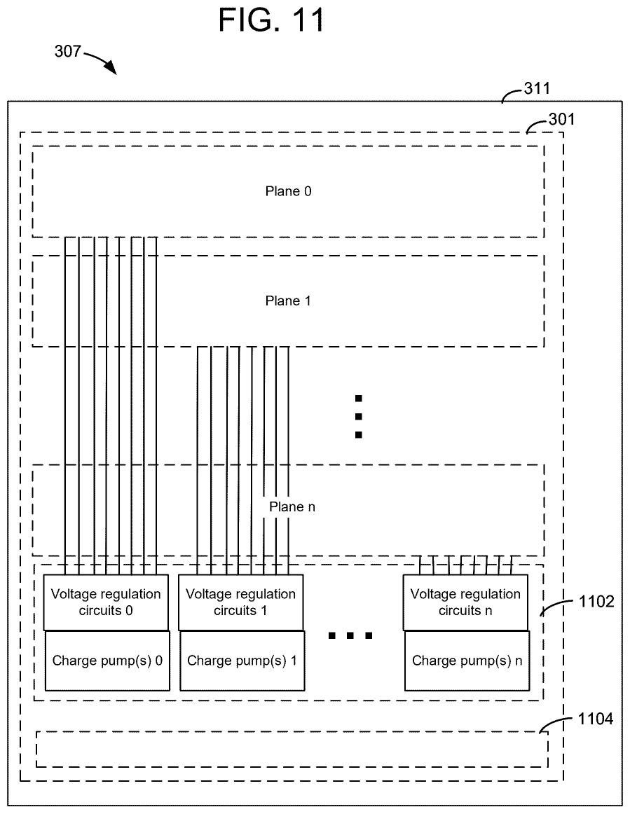

FIG. 11 shows an example of a physical arrangement of charge pumps and voltage regulation circuits on control die 311 in integrated memory assembly 307 formed of control die 311 bonded to memory die 301 (shown by dashed lines in the top-down view of FIG. 11). Memory die 301 includes n portions, each portion formed of a plane in this example (e.g., planes 302 and 304 may be considered examples of different portions of a nonvolatile memory array). Control die 311 includes control circuits for each plane that are located in respective areas that correspond to portions (planes 0-n in this example) of the nonvolatile memory array of memory die 301. For example, “Plane 0” of FIG. 11 shows the portion of memory die 301 occupied by plane 0 and also the respective area of control die 311 that corresponds to plane 0. Pairs of bond pads may connect plane 0 of memory die 301 and control circuits in a respective area of control die 311 for plane 0 (e.g., the area of control die 311 indicated as plane 0 includes array bond pads for bonding to corresponding bond pads of memory die 301). Similarly, “Plane 1” illustrates the portion of memory die 301 occupied by plane 1 and also the respective area of control die 311 corresponding to plane 1 (and where bond pad pairs are located to connect these components).

Charge pumps and voltage regulation circuits for each plane are located together in a common area 1102 that is located in an area of control die 311 that is between respective areas for planes 0-n and an external bond pad area 1104. External bond pad area 1104 (bond pad area) may include bond pads for external connection of integrated memory assembly 307 (e.g., a portion of control die 311 that is not covered by memory die 301 so that bond pads in bond pad area 1104 remain accessible for external connection, for example, to a memory controller). Additional pairs of bond pads may connect planes of memory die 311 with control circuits of corresponding areas of control die 311. Locating voltage regulation circuits for multiple planes (e.g., voltage regulation circuits 0-n for planes 0-n) together in common area 1102 in this configuration may not be ideal. For example, the close proximity of voltage regulation circuits and the extended connections from voltage regulation circuits to different planes (which may be operating asynchronously) may result in cross-talk that may cause errors in read and/or write operations. Connections between voltage regulation circuits and planes are non-uniform in length (e.g., longer from voltage regulation circuits 0 to plane 0 than from voltage regulation circuits n to plane n) and may require significant resources (e.g., a significant number of connections or traces, which may represent a significant portion of one or more layers of metal interconnects).

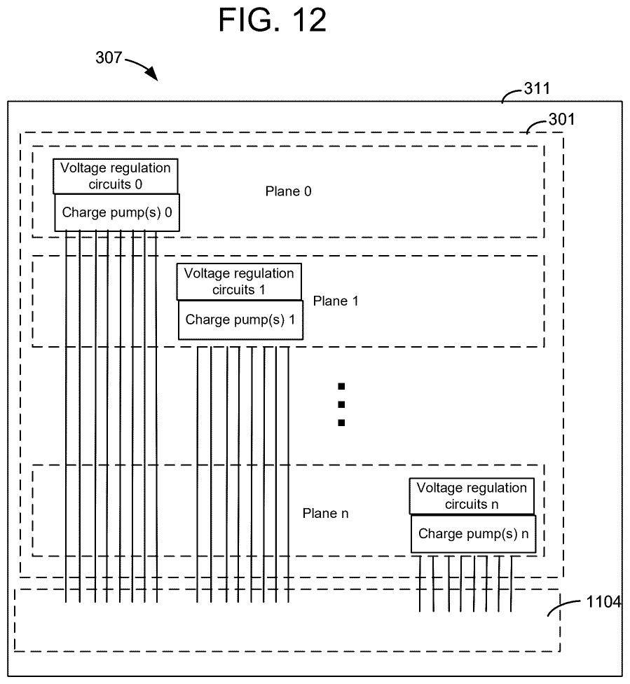

FIG. 12 shows an alternative configuration to that of FIG. 11. In the example of FIG. 12, charge pumps and voltage regulation circuits for each plane are located in respective areas of control die 311 corresponding to the plane. For example, voltage regulation circuits 0 and charge pumps 0 are located in area “Plane 0” of control die 311, which is located directly opposite and is bonded to plane 0 of memory die 301. Similarly, voltage regulation circuits 1 and charge pumps 1 are located in area “Plane 1” of control die 311, which is located directly opposite and is bonded to plane 1 of memory die 301. While this arrangement may result in less cross-talk than the example of FIG. 11, it may not be ideal.

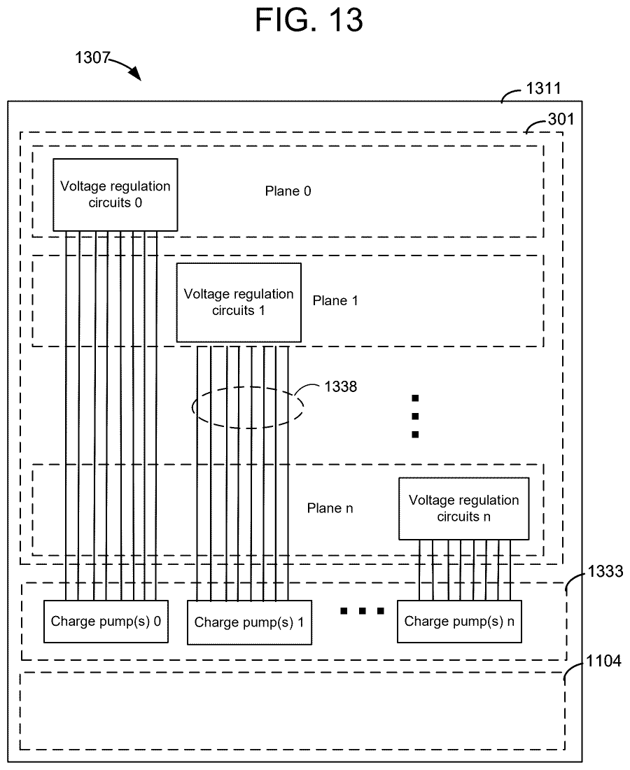

FIG. 13 shows an example of an integrated memory assembly that includes a control die 1311 according to an example of the present technology. In contrast with previous examples, charge pumps and corresponding voltage regulation circuits are separated in control die 1311 and are not located together as previously shown.

In contrast with the example of FIG. 12, control die 1311 shows charge pumps located in charge pump area 1333, which is close to bond pad area 1104 (immediately adjacent in the example of FIG. 13). Voltage regulation circuits are located in respective areas of control die 1311 corresponding to respective planes. For example, voltage regulation circuits 0 are located in the area corresponding to plane 0, voltage regulation circuits 1 are located in the area corresponding to plane 1 and so on. Distributing voltage regulation circuits in this manner provides isolation between voltage regulation circuits for different planes and reduces cross-talk. Locating voltage regulation circuits close to the components (e.g., word lines of a corresponding plane) that they provide voltages to may result in better voltage regulation. Voltage regulation circuits 0-n generate a plurality of corresponding regulated voltages for the corresponding portions of the nonvolatile memory array (planes 0-n respectively). Charge pumps 0-n may be implemented as previously described (e.g., in FIGS. 6A-D and 7) or otherwise. Voltage regulation circuits 0-n may be implemented as previously described (e.g., in FIG. 9) or otherwise.

In contrast with the example of FIG. 12, locating charge pumps close to bond pad area 1104 may provide significant advantages. For example, output current, Iout, of a charge pump may be given by the following equation:

$${I}_{out} = C \frac{( N + 1 ) {V}_{in} - {V}_{out}}{N \cdot {T}_{clock}}$$

Where: C=capacitance, N=number of stages, Vin=input voltage, Vout=output voltage and Tclock=clock period. In order to provide a desired output current and voltage (given Iout and Vout), the capacitance needed depends on Vin (e.g., if Vin is lower, C must be bigger to achieve the same output current and voltage). As Vin drops, C must be increased accordingly. Locating charge pumps as shown in FIG. 12 may result in significant and non-uniform voltage drop between bond pad area 1104 and charge pumps (e.g., charge pumps 0) so that Vin may be significantly lower for at least some charge pumps, which may need correspondingly larger capacitors. In contrast, locating charge pumps for planes 0-n in a charge pump area that is close to bond pad area 1104 results in charge pumps receiving a substantially uniform Vin with little voltage drop from corresponding bond pads in bond pad area 1104.

In the separated arrangement of FIG. 13, fewer connections may be needed between areas corresponding to planes and peripheral regions (e.g., charge pump areas). Voltage drops between charge pumps and corresponding voltage regulation circuits and non-uniformity of such voltage drops may not have significant impact (e.g., voltage regulation circuits 0-n are located at different distances from the charge pump area, which may produce different resistive voltage drops). For example, voltage regulation circuits may be designed to output a regulated voltage at some voltage below a supply voltage provided by a charge pump. Voltage regulation circuits that receive different supply voltages due to different resistance may step down supply voltages by different amounts to achieve substantially uniform regulated voltages. Voltage regulation circuits 0-n may be considered an example of means for separately regulating the plurality of supply voltages for each plane of the plurality of planes at locations corresponding to each plane and at varying distances from the plurality of charge pumps.

In an example, a charge pump generates an erase voltage of about 21 volts (e.g., between 20 volts and 22 volts) and a corresponding voltage regulation circuit generates a regulated erase voltage of about 20 volts, e.g., less than the erase voltage by about 1 volt (e.g., by 0.5 volts to 1.5 volts). The erase voltage may be applied by voltage regulation circuits to word lines of a plane to erase a selected block. In an example, a charge pump generates a read voltage of about 6 volts (e.g., between 5 volts and 7 volts) and a corresponding voltage regulation circuit generates a regulated read voltage of about 5 volts, e.g., less than the read voltage by about 1 volt (e.g., by 0.5 volts to 1.5 volts). A range of different regulated read voltages may be used to perform a read operation (e.g., for reading different data states). The read voltages may be applied by voltage regulation circuits to a selected word line of a selected block of the corresponding plane. In an example, a charge pump generates a write voltage of about 6 volts (e.g., between 5 volts and 7 volts) and a corresponding voltage regulation circuit generates a corresponding regulated write voltage of about 5 volts, e.g., less than the write voltage by about 1 volt (e.g., by 0.5 volts to 1.5 volts). A range of different write voltages may be used to perform a write operation (e.g., for writing different data states). The write voltage may be applied by voltage regulation circuits to a selected word line of a selected block of the corresponding plane.

While the example of FIG. 13 shows connections between charge pumps and voltage regulation circuits of a plane extending across areas associated with other planes (e.g., connections 1338 between charge pumps 1 and voltage regulation circuits 1 for plane 1 extend over the area of control die 1311 corresponding to plane n), other configurations are possible.

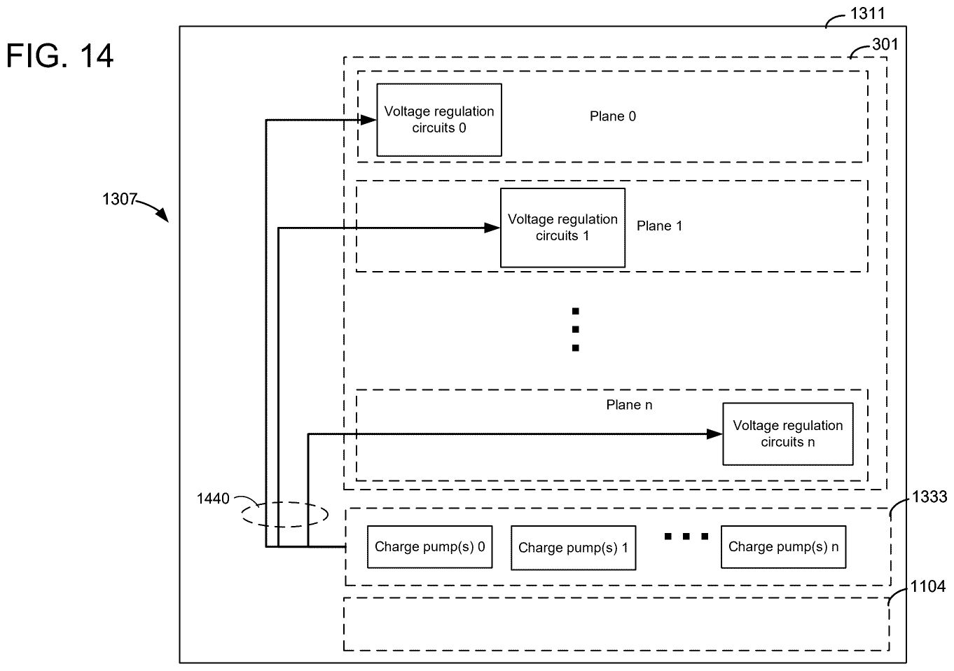

FIG. 14 shows an example in which connections 1440 between charge pumps located in charge pump area 1333 are routed around areas of control die 1311 that are associated with other planes. Routing in this way may reduce cross-talk and may leave space available for other routing in one or more metal layers.

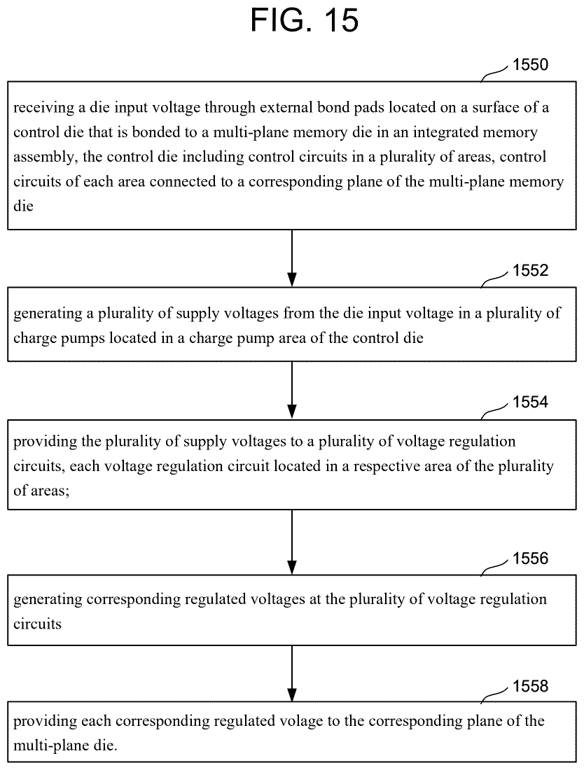

FIG. 15 shows an example of a method that includes receiving a die input voltage through external bond pads located on a surface of a control die that is bonded to a multi-plane memory die in an integrated memory assembly, the control die including control circuits in a plurality of areas, control circuits of each area connected to a corresponding plane of the multi-plane memory die 1550 (e.g., receiving die input voltage through bond pads in bond pad area 1104 of integrated memory assembly 1307), generating a plurality of supply voltages from the die input voltage in a plurality of charge pumps located in a charge pump area of the control die 1552 (e.g., charge pumps in charge pump area 1333) and providing the plurality of supply voltages to a plurality of voltage regulation circuits, each voltage regulation circuit located in a respective area of the plurality of areas 1554 (e.g., to voltage regulation circuits 0-n located in respective areas for plane 0 to plane n). The method further includes generating corresponding regulated voltages at the plurality of voltage regulation circuits 1556 and providing each corresponding regulated volage to the corresponding plane of the multi-plane die 1558 (e.g., providing a read, write or erase voltage to word lines or other components of a corresponding plane).

An example of an apparatus includes one or more control circuits configured to connect to a nonvolatile memory array. The one or more control circuits are configured to receive a die input voltage through external bond pads located on a surface of a die, generate a plurality of supply voltages from the die input voltage in a plurality of charge pumps located in a charge pump area of the die, provide the plurality of supply voltages to a plurality of voltage regulation circuits, each voltage regulation circuit located in a respective area of the die that corresponds to a portion of the nonvolatile memory array and generate a plurality of corresponding regulated voltages at each of the plurality of voltage regulation circuits for the corresponding portion of the nonvolatile memory array.

In one or more example of the above apparatus, the die is a control die with array bond pads located in the respective areas of the control die for bonding to bond pads of a memory die that includes the nonvolatile memory array.

In one or more example of the above apparatus, each portion of the nonvolatile memory array is a plane that consists of a plurality of blocks and each respective area of the die includes control circuits and array bond pads that are specific to a corresponding plane of the nonvolatile memory array.

In one or more example of the above apparatus, each voltage regulation circuit is configured to output at least one of a read voltage, a write voltage or an erase voltage.

In one or more example of the above apparatus, the charge pump area of the die is immediately adjacent to the external bond pads and the plurality of voltage regulation circuits are located at different distances from the charge pump area.

In one or more example of the above apparatus, each voltage regulation circuit includes a current mirror controlled by a comparator.

In one or more example of the above apparatus, each charge pump includes at least one switching stage and a switching regulation circuit.

In one or more example of the above apparatus, the nonvolatile memory array is a 3D NAND flash memory array that includes vertical NAND strings.

In one or more example of the above apparatus, the apparatus further includes a multi-plane memory die that contains the nonvolatile memory array, the multi-plane memory die is bonded to the die to form an integrated memory assembly, each voltage regulation circuit located in a respective area of the die that is directly opposite and is bonded to a corresponding plane of the nonvolatile memory array.

An example of a method includes receiving a die input voltage through external bond pads located on a surface of a control die that is bonded to a multi-plane memory die in an integrated memory assembly, the control die including control circuits in a plurality of areas, control circuits of each area connected to a corresponding plane of the multi-plane memory die; generating a plurality of supply voltages from the die input voltage in a plurality of charge pumps located in a charge pump area of the control die; providing the plurality of supply voltages to a plurality of voltage regulation circuits, each voltage regulation circuit located in a respective area of the plurality of areas; generating corresponding regulated voltages at the plurality of voltage regulation circuits; and providing each corresponding regulated volage to the corresponding plane of the multi-plane memory die.

In one or more example of the above method, generating the plurality of supply voltages includes generating an erase voltage of between 20 volts and 22 volts and generating a corresponding regulated voltage includes generating a regulated erase voltage that is less than the erase voltage by 0.5 volts to 1.5 volts.

In one or more example of the above method, providing the regulated erase voltage to the corresponding plane includes providing the regulated erase voltage to word lines of the corresponding plane.

In one or more example of the above method, generating the plurality of supply voltages includes generating a read voltage of between 5 volts and 7 volts and generating a corresponding regulated voltage includes generating a regulated read voltage that is less than the read voltage by 0.5 volts to 1.5 volts.

In one or more example of the above method, providing the regulated read voltage to the corresponding plane includes providing the regulated read voltage to word lines of the corresponding plane.

In one or more example of the above method, generating the plurality of supply voltages includes generating a plurality of write voltages of between 5 volts and 7 volts and generating a corresponding plurality of regulated write voltages includes for each supply voltage generating a corresponding regulated write voltage that is less than the write voltage by 0.5 volts to 1.5 volts.

In one or more example of the above method, providing the plurality of regulated write voltages to the corresponding plane includes providing the regulated write voltages to a selected word line of the corresponding plane.

In one or more example of the above method, providing the plurality of supply voltages to the plurality of voltage regulation circuits located in respective areas includes providing the plurality of supply voltages over different distances according to locations of respective areas and generating corresponding regulated voltages at the plurality of voltage regulation circuits includes stepping down supply voltages by different amounts.

An example of a memory system includes a plurality of planes of nonvolatile memory cells; a plurality of charge pumps connected to provide a plurality of supply voltages for accessing the plurality of planes; and means for separately regulating the plurality of supply voltages for each plane of the plurality of planes at locations corresponding to each plane and at varying distances from the plurality of charge pumps.

In one or more example of the above system, the plurality of planes of nonvolatile memory cells are located in a memory die, the plurality of charge pumps and the means for separately regulating are located in a control die and the memory die is bonded to the control die to form an integrated memory assembly.

In one or more example of the above system, the control die includes bond pads for external connection of the integrated memory assembly, the plurality of charge pumps are located adjacent to the bond pads and the means for separately regulating are distributed across the control die.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
one or more control circuits configured to connect to a nonvolatile memory array, the one or more control circuits are configured to:
receive a die input voltage through external bond pads located on a surface of a die, generate a plurality of supply voltages from the die input voltage in a plurality of charge pumps located in a charge pump area of the die, provide the plurality of supply voltages to a plurality of voltage regulation circuits, each voltage regulation circuit located in a respective area of the die that corresponds to a portion of the nonvolatile memory array and generate a plurality of corresponding regulated voltages at each of the plurality of voltage regulation circuits for the corresponding portion of the nonvolatile memory array.

2. The apparatus of claim 1, wherein the die is a control die with array bond pads located in the respective areas of the control die for bonding to bond pads of a memory die that includes the nonvolatile memory array.

3. The apparatus of claim 2, wherein each portion of the nonvolatile memory array is a plane that consists of a plurality of blocks and each respective area of the die includes control circuits and array bond pads that are specific to a corresponding plane of the nonvolatile memory array.

4. The apparatus of claim 1, wherein each voltage regulation circuit is configured to output at least one of a read voltage, a write voltage or an erase voltage.

5. The apparatus of claim 1, wherein the charge pump area of the die is immediately adjacent to the external bond pads and the plurality of voltage regulation circuits are located at different distances from the charge pump area.

6. The apparatus of claim 1, wherein each voltage regulation circuit includes a current mirror controlled by a comparator.

7. The apparatus of claim 1, wherein each charge pump includes at least one switching stage and a switching regulation circuit.

8. The apparatus of claim 1, wherein the nonvolatile memory array is a 3D NAND flash memory array that includes vertical NAND strings.

9. The apparatus of claim 1, further comprising a multi-plane memory die that contains the nonvolatile memory array, the multi-plane memory die is bonded to the die to form an integrated memory assembly, each voltage regulation circuit located in a respective area of the die that is directly opposite and is bonded to a corresponding plane of the nonvolatile memory array.

10. A method comprising:
receiving a die input voltage through external bond pads located on a surface of a control die that is bonded to a multi-plane memory die in an integrated memory assembly, the control die including control circuits in a plurality of areas, control circuits of each area connected to a corresponding plane of the multi-plane memory die;
generating a plurality of supply voltages from the die input voltage in a plurality of charge pumps located in a charge pump area of the control die;
providing the plurality of supply voltages to a plurality of voltage regulation circuits, each voltage regulation circuit located in a respective area of the plurality of areas;
generating corresponding regulated voltages at the plurality of voltage regulation circuits; and
providing each corresponding regulated volage to the corresponding plane of the multi-plane memory die.

11. The method of claim 10, wherein generating the plurality of supply voltages includes generating an erase voltage of between 20 volts and 22 volts and generating a corresponding regulated voltage includes generating a regulated erase voltage that is less than the erase voltage by 0.5 volts to 1.5 volts.

12. The method of claim 11, wherein providing the regulated erase voltage to the corresponding plane includes providing the regulated erase voltage to word lines of the corresponding plane.

13. The method of claim 10, wherein generating the plurality of supply voltages includes generating a read voltage of between 5 volts and 7 volts and generating a corresponding regulated voltage includes generating a regulated read voltage that is less than the read voltage by 0.5 volts to 1.5 volts.

14. The method of claim 13, wherein providing the regulated read voltage to the corresponding plane includes providing the regulated read voltage to word lines of the corresponding plane.

15. The method of claim 10, wherein generating the plurality of supply voltages includes generating a plurality of write voltages of between 5 volts and 7 volts and generating a corresponding plurality of regulated write voltages includes for each supply voltage generating a corresponding regulated write voltage that is less than the write voltage by 0.5 volts to 1.5 volts.

16. The method of claim 15, wherein providing the plurality of regulated write voltages to the corresponding plane includes providing the regulated write voltages to a selected word line of the corresponding plane.

17. The method of claim 10, wherein providing the plurality of supply voltages to the plurality of voltage regulation circuits located in respective areas includes providing the plurality of supply voltages over different distances according to locations of respective areas and generating corresponding regulated voltages at the plurality of voltage regulation circuits includes stepping down supply voltages by different amounts.

18. A memory system comprising:
a plurality of planes of nonvolatile memory cells;
a plurality of charge pumps connected to provide a plurality of supply voltages for accessing the plurality of planes; and
means for separately regulating the plurality of supply voltages for each plane of the plurality of planes at locations corresponding to each plane and at varying distances from the plurality of charge pumps.

19. The memory system of claim 18, wherein the plurality of planes of nonvolatile memory cells are located in a memory die, the plurality of charge pumps and the means for separately regulating are located in a control die and the memory die is bonded to the control die to form an integrated memory assembly.

20. The memory system of claim 19, wherein the control die includes bond pads for external connection of the integrated memory assembly, the plurality of charge pumps are located adjacent to the bond pads and the means for separately regulating are distributed across the control die.
